(19) United States
(12) Patent Application Publication
(10) Pub. No.: US 2008/0123297 A1
(43) Pub. Date: May 29, 2008

(54) Hybrid clamshell blade system

(75) Inventors: Donald E. Tilton, Colton, WA (US); Tahir Cader, Liberty Lake, WA (US); Eric Grabowski, Spokane Valley, WA (US); Ryan J. Baddeley, Liberty Lake, WA (US); P. Harley Park, (US); Peter Mohr, Hayden, ID (US); Benjamin H. Tolman, Meridian, ID (US); Norman O. Alder, Liberty Lake, WA (US)

Correspondence Address: Dale Mohlenhoff, 2218 N. Molter Rd., Liberty Lake, WA, 99019, US

(73) Assignee: Isothermal Systems Research, Inc., Liberty Lake, WA (US)

(21) Appl. No.: 11/803,750

(22) Filed: May 15, 2007

Related U.S. Application Data
(60) Provisional application No. 60/800,728, filed on May 15, 2006.

(51) Int. Cl. H05K 7/20; F25D 23/12

(52) U.S. Cl. 361/700; 62/259.2

(57) ABSTRACT

A hybrid clamshell system encapsulates two of the six sides of an electronic circuit board to provide a high heat density solution and environmental protection. The clamshell enclosures seal to both sides of the PCB and contain fluid shut-off couplings. A two-phase cooling system directs a coolant via a supply path located in the sidewall of the enclosure to one or more cooling modules and collects the coolant via a return path within the enclosure. With the addition of an inject/eject mechanism attached to the clamshell, the fully assembled blade can be “fluid hot-swapped” in and out of the chassis with negligible loss of coolant. The interrelation of the clamshell module and it's implementation in an exemplary system are detailed herein.

### CROSS REFERENCE TO RELATED APPLICATIONS

This application claims the benefit of U.S. Provisional Application No. 60/800,728 filed May 15, 2006, which is incorporated by reference in its entirety. This application is also related to U.S. Provisional Patent Application No. 60/775,496 filed on Feb. 21, 2006, U.S. Patent Application Number 2005/0195570, and U.S. Pat. No. 6,958,911, which are incorporated herein by reference as well.

### STATEMENT REGARDING FEDERALLY SPONSORED R&D

This invention was made with Government support under contract #N68335-04-D-0008-2P02 awarded by the Defense Micro Electronics Agency (DMEA). The Government has certain rights in this invention.

### BACKGROUND

This invention relates generally to an evaporative liquid cooling system in a clamshell enclosure.

Liquid cooling is well known in the art of cooling electronics. As air cooling heat sinks continue to be pushed to new performance levels, so has their cost, complexity, and weight. Because computer power consumptions will continue to increase, liquid cooling systems will provide significant advantages to computer manufacturers and electronic system providers.

Liquid cooling technologies utilize a liquid coolant to remove heat from an electronic component or components. Liquids can hold more heat and transfer heat at a rate many times that of gasses such as air. Single-phase liquid cooling systems place a liquid in thermal contact with the component to be cooled. With these systems, the liquid coolant absorbs heat as sensible energy. Other liquid cooling systems, such as spray cooling, are two-phase processes. In two-phase cooling systems, heat is absorbed by the cooling fluid primarily through latent energy gains. Two-phase cooling, commonly referred to as evaporative cooling, allows for more efficient, more compact, and higher performing liquid cooling systems than systems based on single-phase cooling.

An exemplary two-phase cooling method is spray cooling. Spray cooling uses a pump to supply liquid coolant to one or more nozzles, which transform the coolant supply into fine droplets. These droplets impinge the surface of the component to be cooled and can create a thin coolant film if properly applied and managed. Energy is transferred from the surface of the component to the thin-film of coolant. The absorbed heat causes the thin-film to turn to vapor. This vapor is then removed from the component, condensed (often by means of a heat exchanger or condenser), and returned to the pump.

Significant efforts have been expended in the development and optimization of liquid cooling. A dissertation by Tilton entitled “Spray Cooling” (1989), available through the University of Kentucky library system, describes how optimization of spray cooling system parameters, such as droplet size, distribution, and momentum can create a thin coolant film capable of absorbing high heat fluxes. In addition to the system parameters described by the Tilton dissertation, U.S. Pat. No. 5,220,804 provides a method of increasing a spray cooling system's ability to remove heat. The '804 patent describes a method of managing system vapor that further thins the coolant film, which increases evaporation, improves convective heat transfer, and improves liquid and vapor reclaim.

Dielectric fluids such as FLUORINERT® (a trademark of 3M Company) are well-suited for use in electronic cooling systems, as they are safe for electronic components, systems, and the environment. The fluids have boiling points close to atmospheric conditions and have latent heat of vaporization values that provide efficient two-phase cooling.

### BRIEF SUMMARY OF THE INVENTION

A liquid cooling system enclosed in a clamshell enclosure is thus provided for achieving maximum performance, power density, and electronics density inside a system that has characteristics of user-friendly serviceability, redundancy, and high availability. Further, in a data center environment, the hybrid clamshell system enables the user to capture over 80% of the heat and reject this to facility water. In a more extreme environment, the environmental isolation is of great importance. In addition, the hybrid clamshell system provides a full board cooling solution for high power density components, and creates a liquid-cooled building block that is form factor independent. In other words, the building block could be used on cPCI, ATX, VME, and mezzanine cards (AMC, PMC, etc.). This system is not limited to blade form factors, since other embodiments can be used.

In one embodiment, the clamshell enclosure encapsulates two of the six sides of a circuit board to provide a high heat density cooling solution and environmental protection to a commercial off-the-shelf (COTS) printed circuit board (PCB). Typically a COTS PCB will consist of a component bearing side that requires increased cooling, and a non-component bearing side, though in some cases components may be on either side of the PCB. In either case one side of the board typically has more and or higher power electronic components than the other side and therefore requires additional cooling. The clamshell enclosure provides a seal to these two sides of the PCB and contains fluid shut-off couplings in appropriate locations consistent with the cooling requirements. In one embodiment, a two-phase cooling system directs coolant via a supply path located in the sidewall of the enclosure to one or more cooling modules and collects the coolant via a return path within the enclosure.

With the addition of an inject/eject mechanism attached to the clamshell, the fully assembled blade can be “fluid hot-swapped” in and out of a system level chassis or subrack (common to cPCI or VME form factors, for example) with negligible loss of coolant (less than 0.05 mL). The fact that the coolant system remains closed during the removal and insertion of blades, provides an unprecedented level of serviceability.

Another key feature of the hybrid clamshell system is to provide a solution for deployment of dense stacked memory that otherwise cannot be air-cooled as well as deployment of air-cooled or spray cooled RTMs (rear transition modules) that enable the use of higher powered network (GigE, Infiniband) chips, graphics chips or other components that cannot be air-cooled. This system provides increased rack space due to the shallow chassis depth achievable.

These and other features, aspects, and advantages of various embodiments of the invention will become better understood with regard to the following description and accompanying drawings.

### BRIEF DESCRIPTION OF THE DRAWINGS

FIG. 1 is an exploded view of a preferred embodiment of an entire clamshell assembly.

FIG. 2a is a lower perspective view showing the inside of the half of a clamshell enclosure that surrounds the component bearing side of an electronics card.

FIG. 2b is an upper perspective view showing the half of a clamshell enclosure that surrounds the component bearing side of an electronics card.

FIG. 3 is an exploded lower perspective view of the half of a clamshell enclosure that surrounds the component bearing side of an electronics card.

FIG. 4a is a sectional view showing the coolant channel created in the clamshell wall.

FIG. 4b is a bottom view showing the coolant routing in the clamshell side wall.

FIG. 5a is a sectional view showing atomizer locations in the clamshell wall.

FIG. 5b is a bottom view of another embodiment of the half of a clamshell enclosure that surrounds the component bearing side an electronics card.

FIG. 5c is a broken out sectional view showing the fluid couplings.

FIG. 6a is a perspective view of a clamshell assembly showing the inject/eject lever mechanism in its extended state.

FIG. 6b is a perspective view of a clamshell assembly showing the inject/eject lever mechanism in its retracted state.

FIG. 7 is an exploded perspective view that shows the CPU with attached heat spreader assembly.

FIG. 8 is an exploded perspective view of another embodiment of clamshell construction.

FIG. 9a is a top view of a clamshell assembly.

FIG. 9b is a partial section side view of a clamshell assembly depicting side and angled sprays.

FIG. 10a is a top view of a clamshell assembly.

FIG. 10b is a side sectional view of a clamshell assembly showing center structural support.

FIG. 11a is a perspective side view of a clamshell assembly.

FIG. 11b is a detail perspective view of a clamshell assembly showing the fingered retainer clips and sidewall groove.

FIG. 12 is a underside perspective view showing an embodiment of the inside of the half of a clamshell enclosure that surrounds the component bearing side an electronics card that implements retainer clips.

FIG. 13 is a perspective view of a clamshell assembly.

FIG. 14 is a rear perspective view of a hybrid cooling electronics subrack that utilizes clamshell cooling modules.

FIG. 15 is an exploded perspective view of a hybrid cooling electronics subrack that utilizes clamshell cooling modules.

FIG. 16 is a front perspective view of a hybrid cooling electronics subrack showing how clamshell cooling modules are inserted.

FIG. 17 is a front perspective view of an exemplary implementation of a hybrid cooling electronics subrack into a 19″ rack.

FIG. 18 is another front perspective view showing fluid connectivity between the clamshell cooling module and the hybrid cooling electronics subrack.

FIG. 19 is a side section view showing coolant delivery normal to the surface within a clamshell assembly.

FIG. 20 is a side section view showing how narrow gap cooling is achieved within a clamshell assembly.

FIG. 21 is a mechanical block diagram of a hybrid cooling system

FIG. 22 is a mechanical block diagram of a clamshell cooling module.

FIG. 23a is a front perspective view of the hybrid cooling system coolant manifold.

FIG. 23b is a back perspective view of the hybrid cooling system coolant manifold.

FIG. 23c is a front view of the hybrid cooling system manifold.

FIG. 24a is a sectional side view of the hybrid cooling system manifold showing the supply ports.

FIG. 24b is a second sectional side view of the hybrid cooling system manifold showing the return ports.

FIG. 25a is a front perspective view of an alternative hybrid cooling system manifold embodiment.

FIG. 25b is a rear perspective view of an alternative hybrid cooling system manifold embodiment.

FIG. 26 is a front perspective view demonstrating the interconnection between a clamshell cooling module and hybrid cooling system manifold, and an electronic backplane within a hybrid cooling electronics subrack, subrack enclosure not shown.

### DETAILED DESCRIPTION OF THE PREFERRED EMBODIMENTS

Many of the fastening, connection, manufacturing and other means and components utilized in this invention are widely known and used in the field of the invention described, and their exact nature or type is not necessary for an understanding and use of the invention by a person skilled in the art or science; therefore, they will not be discussed in significant detail. Furthermore, the various components shown or described herein for any specific application or embodiment of any element may already be widely known or used in the art or by persons skilled in the art or science; therefore, each will not be discussed in significant detail.

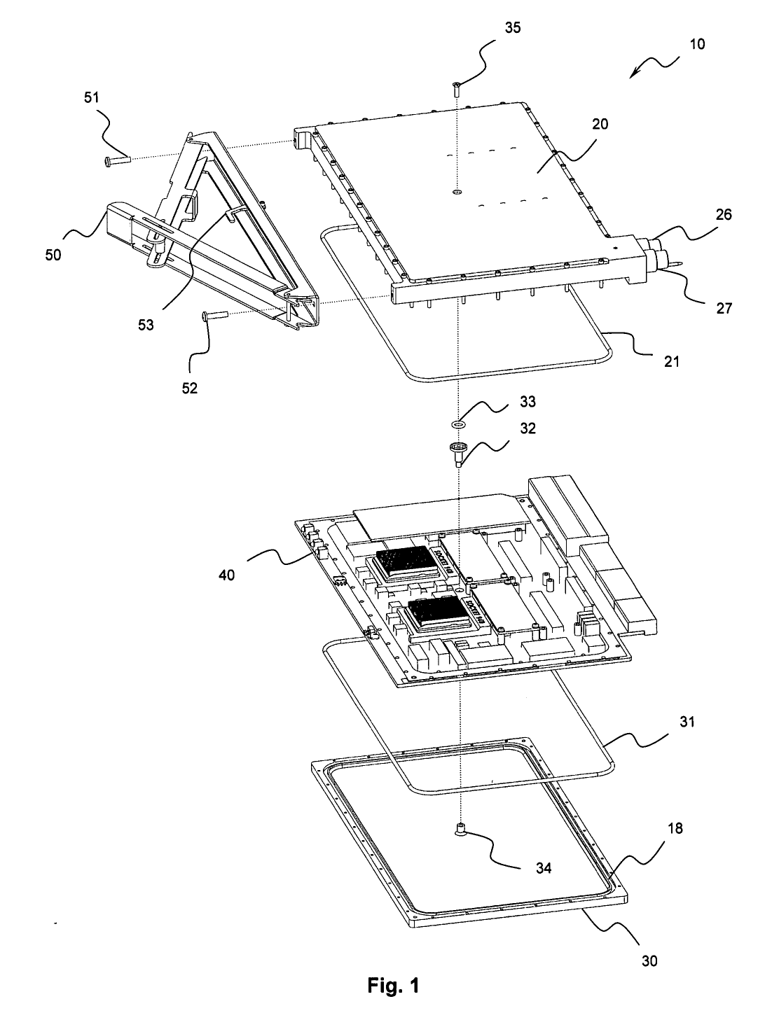

Turning now descriptively to the drawings, in which similar reference characters denote similar elements throughout the several views, FIGS. 1 through 25 illustrate a hybrid clamshell system. This specification will provide a thorough description of the embodiments described, however some features of the overall system likely have been omitted but will be apparent to those skilled in the art.

### A. Hybrid Clamshell System

FIG. 1 illustrates the preferred embodiment of an entire hybrid clamshell system assembly 10. The enclosure consists of an upper portion or component side of the enclosure 20 and a lower portion or solder side of the enclosure 30. Both the upper portion of the enclosure 20 and the lower portion of the enclosure 30 contain o-ring channels 19 and 35 for receiving an o-ring 21 and 31, respectively that seals the enclosure to the electronic circuit board 40. The hybrid clamshell system assembly 10 which encapsulates two of the six sides of a circuit board provides a high heat density solution and environmental protection to proprietary or custom board or a commercial off-the-shelf (COTS) printed circuit board (PCB). The fact that four sides of the board and in some embodiments, portions of the two other sides are outside of the enclosure and not in contact with the liquid coolant allows for the use of native or COTS electrical and power connectors. An exemplary multi-processor board is capable of receiving well over 500 Watts of power through COTS connectors. It also has many high-speed signals coming through the COTS connectors, such as but not limited to, Infiniband, Serial ATA, 1 Gb Ethernet, USB, and the like. Power entry and I/O can come from any and all of the four exposed edges of the PCB or from unsealed portions of the main two sides. All the signals and power are routed in and out of the clamshell enclosure through industry standard vias on the PCB.

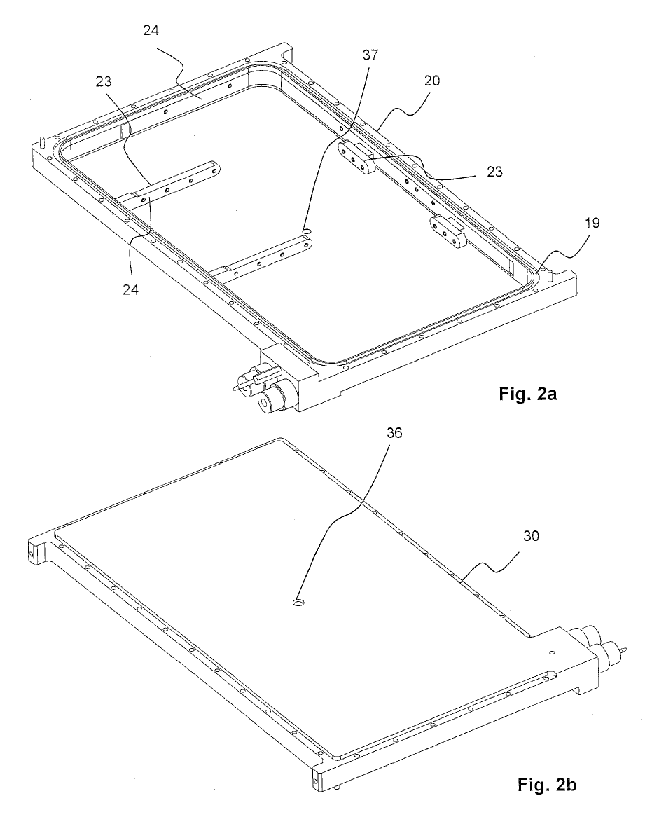

FIGS. 2 and 2a illustrate coolant routing channel 22. In FIG. 2a, the upper portion of the enclosure 20 is shown with coolant routing channel 22 as well as one or more spray plate extensions 23 and one or more spray plates 24 contained both within the wall of coolant routing channel 22 as well as in the sides of spray plate extensions 23. The spray plate extensions 23 allow for additional spray in PCB areas where high heat fluxes (W/cm²) exist. Returning to FIG. 1, a center post or post support member 32 can be used to provide for more support for the two portions 20 and 30 of the enclosure. The center post 32 uses standard fasteners 34 and 35 for securing the two portions 20 and 30 of the enclosure. The center post does not have to be located in the center and can be positioned anywhere on the two portions 20 and 30 of the enclosure where sufficient structural support is achieved. A standard o-ring 33 seals to an inner surface on one side. The center post 32 allows the clamshell walls to be thinner and lighter yet retain their shape under pressure loading conditions. An inject/eject lever 50 can also be attached to the upper portion of the enclosure 20 using standard fasteners 51 and 52. The inject/eject lever 50 provides for ease of insertion of the hybrid clamshell system assembly 10 into a subrack and for ease of removal for maintenance or replacement. The inject/eject lever 50 includes a safety switch lock 53 to lock the mechanism in place during operation to prevent any unintended dislodging of the hybrid clamshell system assembly 10. The single-hand-operation inject/eject lever 50 is designed to overcome large insertion loads through mechanical advantage. The inject/eject upper and lower levers are designed as a linkage and operated simultaneously with one hand. The linkage ensures the blade is injected smoothly and squarely every time the blade is inserted or retracted from a subrack. The linkage design also provides a substantial mechanical advantage over standard inject/eject levers. The increased injection forces due to commonly implemented dense, high pin count connectors (utilized to handle the enhanced functionality of enabled PCB's) are handled more easily with this inject/eject lever 50. The inject/eject lever 50 is fastened directly to the clamshell—not to the PCB and therefore enables smooth lever operation and minimizes potential damage to a high-end, high cost enabled PCB's and their corresponding backplanes.

A safety switch lock 53 is mechanically coupled to the inject/eject lever 50. The safety switch lock 53 must be unlocked for the inject/eject lever 50 to operate. If the PCB is powered at the time of ejection, the switch signals an emergency power-down and will prevent power being applied without a sufficient coolant supply. This allows for “Fluid Hot-swap” capability providing for the connecting or disconnecting of individual blades that are connected to a common backplane and protection of the electronic devices. This capability is similar to the “hot-swap” capability of a standard cPCI or ATCA blades, but is novel in that it incorporates an electrical shutoff with an interruption in coolant supply.

Coolant supply shutoff valve 26 and coolant exit shutoff valve 27 are provided to allow for removing the hybrid clamshell assembly during operation with negligible loss of coolant. The preferred embodiment utilizes coolant shutoff valves 26 and 27 that are semi-custom fluid couplings manufactured by Eaton-Aeroquip. The selected connectors allow for up to 0.025″ radial misalignment, which enables a hard-mounted connection at the rear of the blade (end opposite the user), in-line with the backplane connectors. Though they require additional features on the blade and chassis to lock them in place, these connectors are designed for low pressure drop, low leakage, and high reliability. Other connectors could be used so long as they meet the pressure drop, flow, leakage, and reliability requirements of the system. It is important to note that though the preferred embodiment implements blind mate style connectors other connection styles are considered and are possible within the scope of this invention. For example the coolant supply and return can, be routed through the front of the blades thereby allowing latching connections to be used. Because the coolant routing is optimized for minimal volume, in this invention, by routing through the clamshell walls, fluid connections can also be achieved through other parts of the structure as well. For example, the coolant could be routed through the top wall if desired. Another option is to route the coolant through tubes (copper, polymer or other) on the inside of the clamshell. There can also be different techniques for fastening or clamping the enclosures to the PCB. For example, a C-clip style of hardware to clamp the two halves together can be used. Other embodiments include an additional return vapor port. Still further embodiments include different locations for the supply and return fluid couplings. The couplings could either be blind-mate or self-latching (or other type) in any of these cases.

Typically, the coolant used in the system is Fluorinert PF 5060, a 3M manufactured fluid. The system is also capable of using PF5050 and PF5052 with some variations in performance, pressure, gassing, and operating temperatures. The system could also operate with other dielectrics. Refrigerants and water can be utilized as a secondary cooling loop or as the primary coolant so long as it is not in direct contact with the electronics.

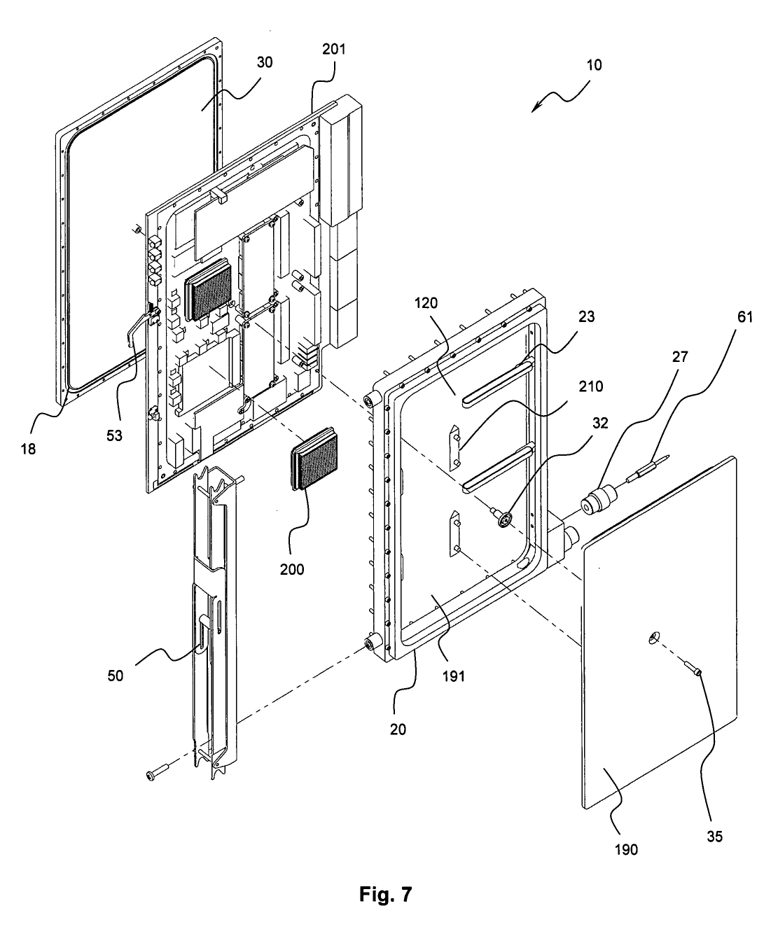

Occasionally Fluorinert incompatibility is encountered. One example is a commercially available normally air cooled CPU that comes standard with a breather hole on the top of the integrated heatsink, as well as breather holes where the integrated heatsink attaches to the CPU's carrier. To enable the use of commercially available CPUs in the hybrid clamshell system assembly 10, it is necessary to either replace the Fluorinert-incompatible TIMs with Fluorinert-compatible TIMs, or to redesign the integrated heatsink to enable sealing the integrated heatsink completely to the CPU carrier (eliminate all breather holes). For either case, specially designed custom integrated heatsinks are preferable. These heatsinks include features that optimize it for use in a liquid cooling environment (i.e. improve heat removal, liquid-vapor drainage, coolant compatibility, etc.), and that also allow for excellent sealing to the CPU carrier (if necessary). The heatsinks are also customized to each CPU, taking into account the number of cores, as well as number and distribution of hotspots. The custom heatsinks are then retrofitted to commercially available (normally air cooled) CPUs. The separate CPU assembly 200 and PCB assembly 201 are shown in FIG. 7 below.

Referring now to FIGS. 2a and 2b, the upper portion of the enclosure 20 and the lower portion of the enclosure 30 are shown. As previously described, the spray plate extensions 23 and spray plates 24 are shown in the upper portion of the enclosure 20. Also, center post hole 37 in the upper portion of the enclosure 20 and center post hole 36 in the lower portion of the enclosure are shown. The center post holes 37 and 36 provide a mounting point for the center post 32 described in FIG. 1.

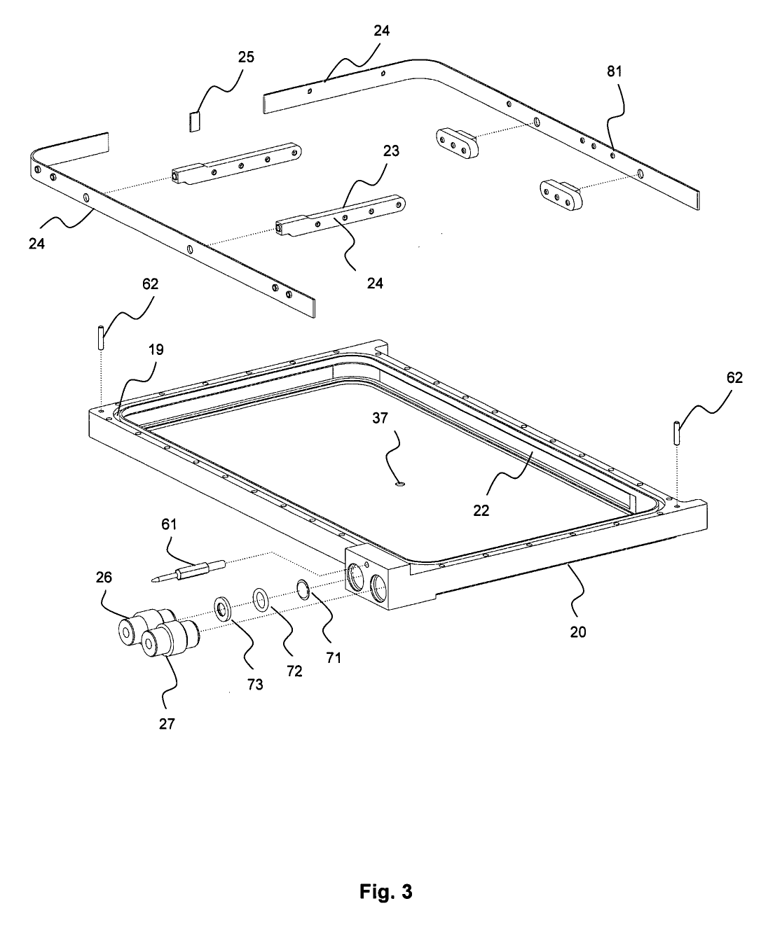

FIG. 3 shows an exploded view of the upper portion of the enclosure 20. The upper portion 20 includes atomizer or spray plate 24 that provide structure to the coolant routing channel 22. “Clamshell” enclosures are mounted (using fasteners, retention clips, etc.) on opposite sides of a PCA (“component-side” and “solder-side”). Each side requires a “sealing surface” keep-out zone that extends perpendicularly outward from the PCB. The proposed manifold design takes advantage of this keep-out zone by incorporating the coolant path into the clamshell sidewalls directly over this keep-out zone. An “undercut” is made into the clamshell's sidewall, which creates three sides of the manifold's rectangular cross-section. The fourth wall of the manifold is created by assembling a separate part spray plate 24 which is attached as part of an assembly process. Since the spray plate 24 is a separate low-cost part, atomizer placement and quantities used can easily be re-configured independent of the more costly clamshell portion 20.

The splice plate 25 is for closing certain portions of the coolant routing channel 22 that are not needed to deliver spray in a particular application. The spray plate extensions 23 attach to the spray plates 24 with standard fasteners, and themselves house additional spray plates 24. The upper portion 20 also includes alignment pins 61 and 62 to provide for ease of assembly and greater structural support. A field replaceable supply filter 71 can also be used in this system to provide for a cleaner coolant entering the hybrid clamshell system assembly 10 via coolant supply shutoff valve 26. A filter seal 72 and a filter seal compression ring 73 are also used when using the filter seal 72 to maintain the integrity of the sealed hybrid clamshell system assembly 10.

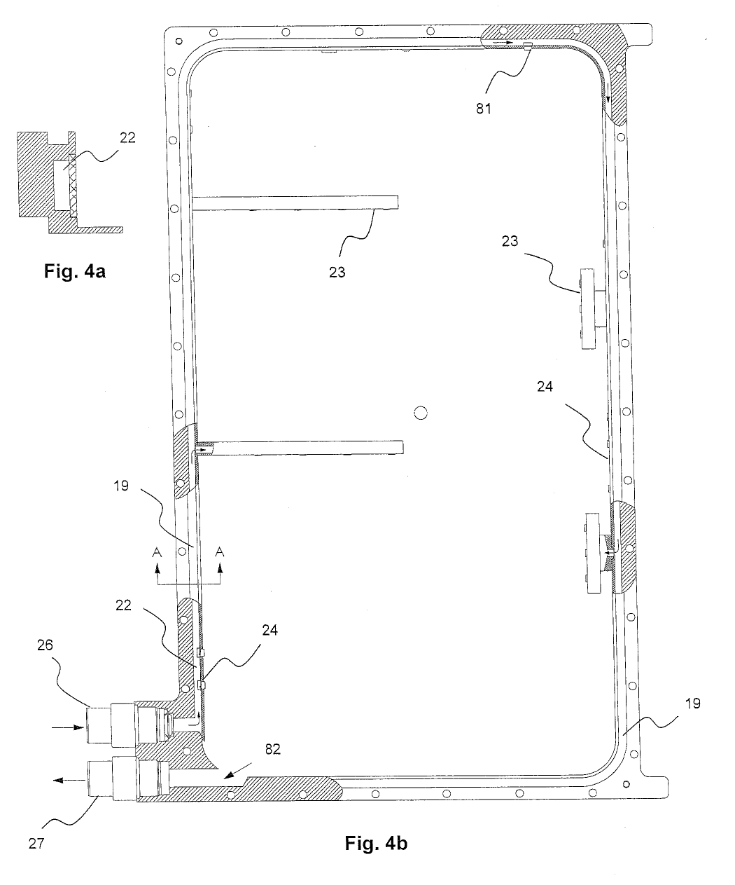

FIGS. 4a and 4b shows the coolant routing channel 22 and the vapor/liquid return 82. The coolant routing channel 22 directs the coolant from the supply shutoff valve 26 into the atomizers 81 housed within the spray plate 24. The vapor and liquid mixture returns through the vapor/liquid return 82 and exits through coolant exit shutoff valve 27.

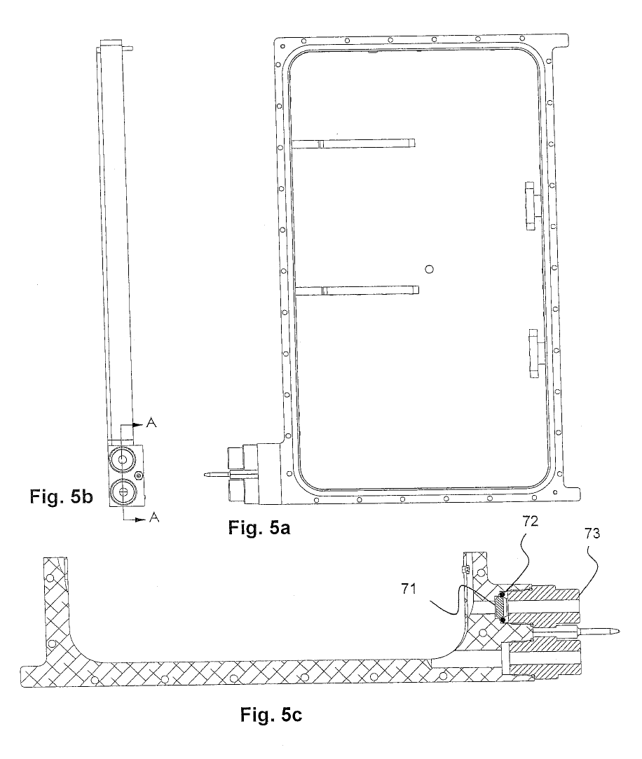

FIGS. 5a and 5b shows further detail of the supply filter 71, filter seal 72 and filter seal compression ring 73 and its assembly in the coolant supply shutoff valve 26.

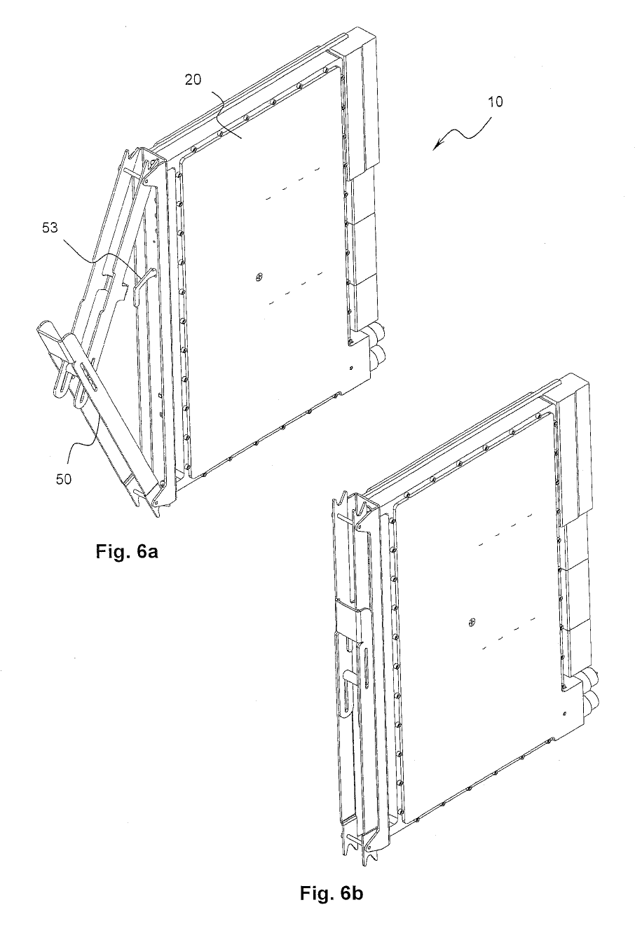

FIGS. 6a and 6b shows the ejected position and the closed and locked position of the inject/eject lever 50.

FIG. 7 shows another embodiment of the hybrid clamshell system assembly 10. In this embodiment, the upper portion 20 acts as a reservoir 191 for the coolant and the spray modules 28 are positioned to spray through the upper portion 20 to the electronic components to be sprayed. In this case, a CPU assembly 200 and PCB assembly 201 which are optimized for heat transfer are fitted to the electronic circuit board. The upper portion 20 of the enclosure forms a cavity or reservoir 191 that is enclosed by a cover 190. The reservoir 191 includes one or more coolant deflection ramps 210 and one or more spray module extensions 23. The coolant enters through the supply shutoff valve 27 into the reservoir 191 and is sprayed onto the CPU assembly 200 and the PCB assembly 201 through the spray module extensions 23. The remainder of the hybrid clamshell system 10 is identical to the FIG. 1 embodiment and includes the inject/eject lever 50 and the center support 32.

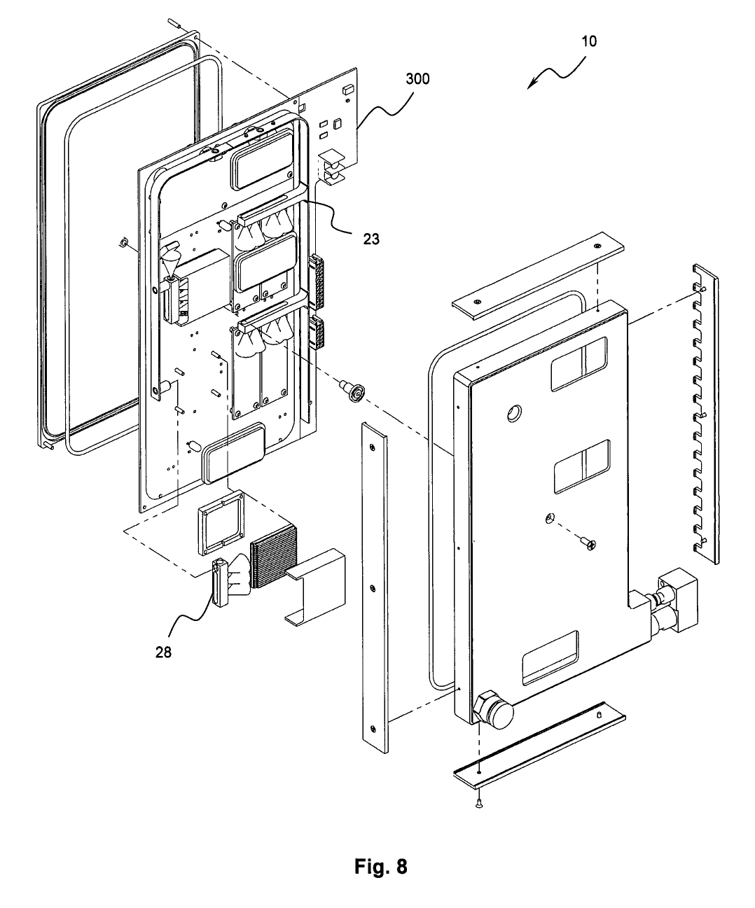

FIG. 8 shows yet another embodiment of the hybrid clamshell system assembly 10. In this embodiment, the spray modules 28 and spray module extensions 23 are assembled on the PCB assembly 300 and sprayed at an angle or in a transverse fashion. It is also possible to use narrow gap spray as previously disclosed in U.S. Pat. No. 7,104,078 filed Aug. 5, 2004. With narrow gap spray, a plurality of side-spraying nozzles are arrayed across a custom featured heat spreader in a narrow gap. It should be noted that the narrow gap feature does not require a custom featured heat spreader, however, this is the preferred design in this embodiment. The additional surface area enhances the heat transfer which reduces component temperature. The processors are modified by removing the OEM heat spreader and attaching the custom heat spreader via a thermal interface material (TIM). The TIM, for example, could be a traditional thermal grease, liquid metal alloy, or solder. Thermal resistances of 0.15 C/N for a 90 W Opteron processor, for example, have produced temperature differences (from spray inlet temperature to diode temperature) of 13° C. In this embodiment, the upper portion of the enclosure may also include spray modules and spray module extensions in addition to those on the PCB assembly. More recently, manufacturers have been deploying solder interfaces. In this case, a custom heat spreader is attached directly to the surface of the integrated heatsink.

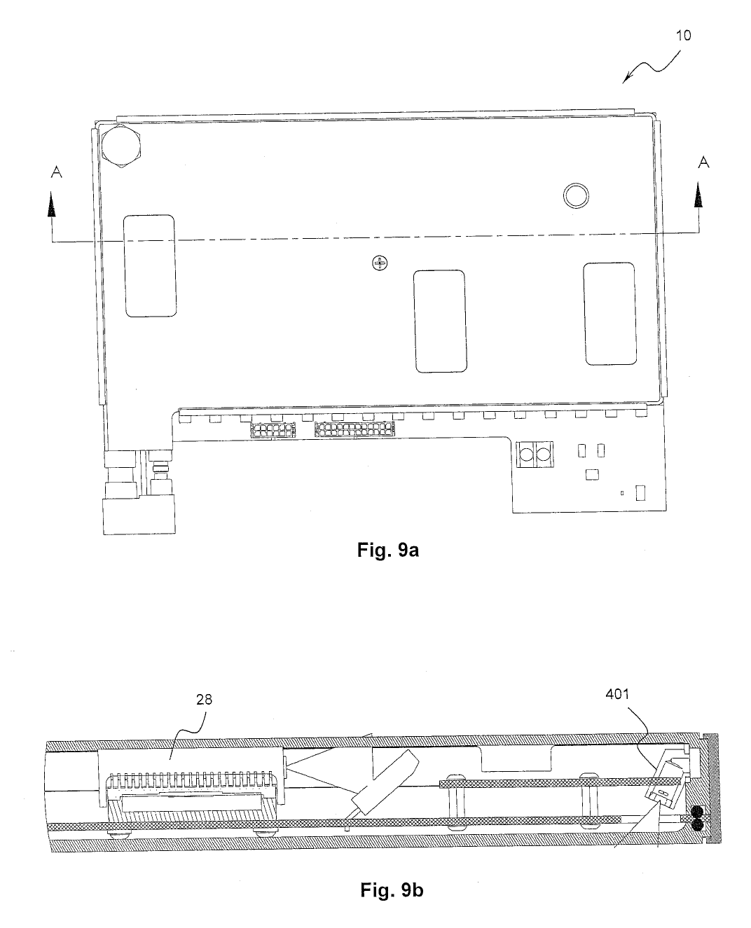

FIGS. 9a and 9b show a partial cross section of the closed hybrid clamshell system assembly 10. The spray module 28 and angled spray module 401 allow for precise spray disposal to address the hotspots on the electronic circuit board.

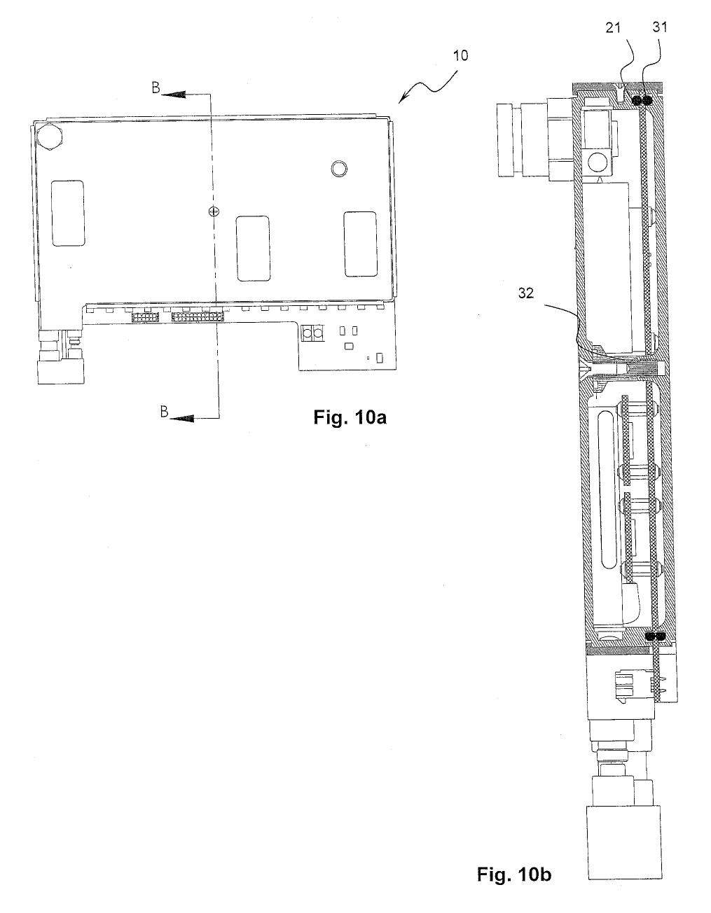

FIG. 10 shows another aspect of the hybrid clamshell system assembly 10, in particular showing the placement and attachment for the center post 332.

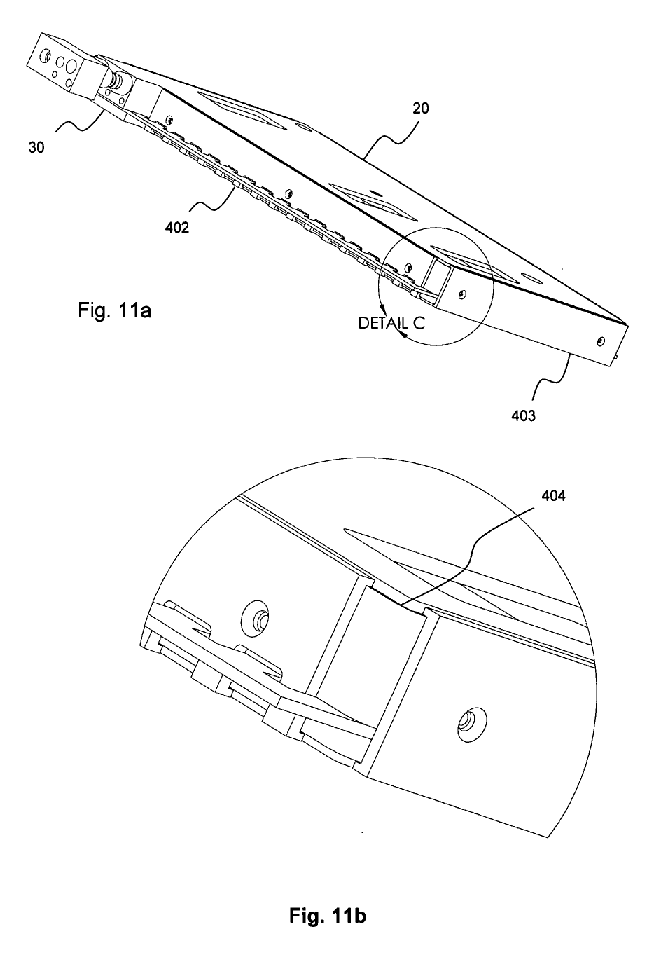

FIGS. 11a and 11b show the retainer clips that are used to hold the upper portion 20 and lower portion 30 of the enclosure together and retain the seal. The retainer clips consist of a fingered retainer clip 402 and a retainer clip 403. Both the fingered retainer clip 402 and the retainer clip 403 serve to provide enough pressure to press the o-ring against the PCB surface and the enclosure to provide a leak proof seal. FIG. 11b further shows a retainer clip to retainer flexible attachment member 404 that forms the transitions between the fingered retainer clip and the retainer clip to hold the various pieces together and seal the corners.

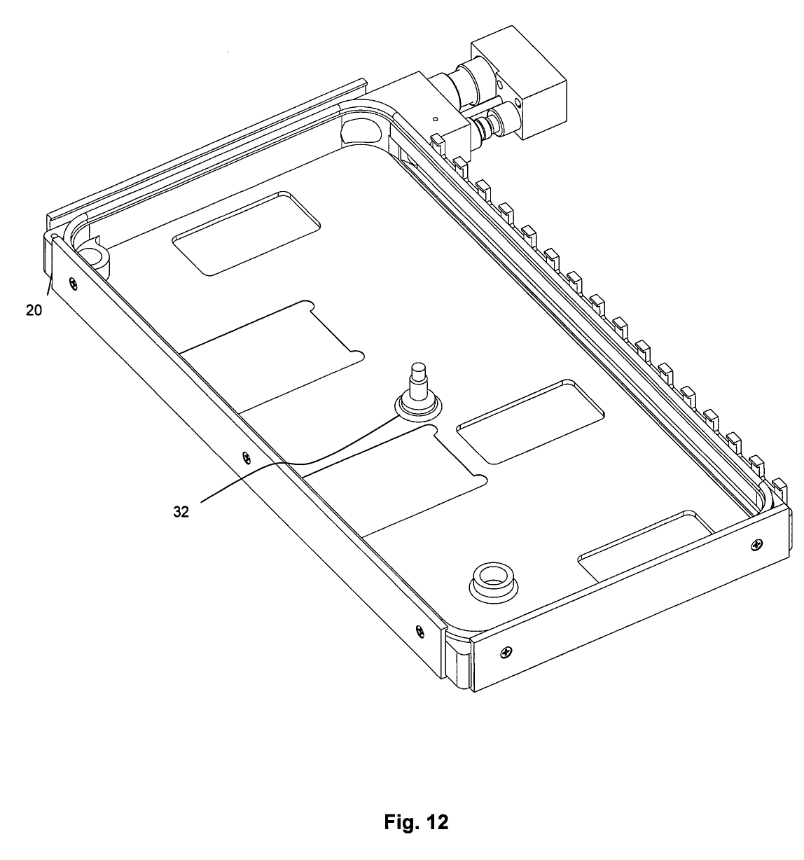

FIG. 12 shows a view of the upper portion 20 of the enclosure with the center post 32 installed and without the PCB assembly 201.

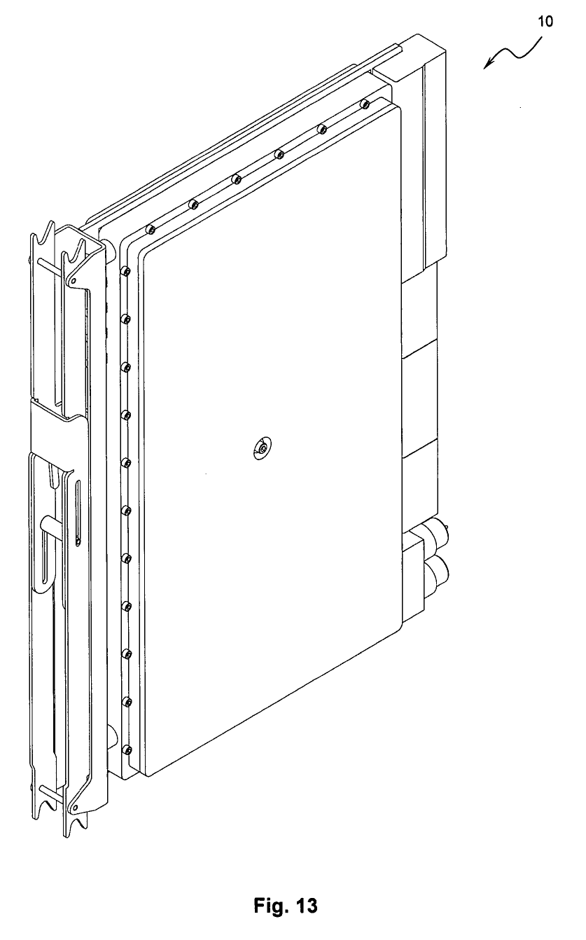

FIG. 13 shows the hybrid clamshell system assembly 10 in a fully closed, locked and sealed position.

### B. Rack System

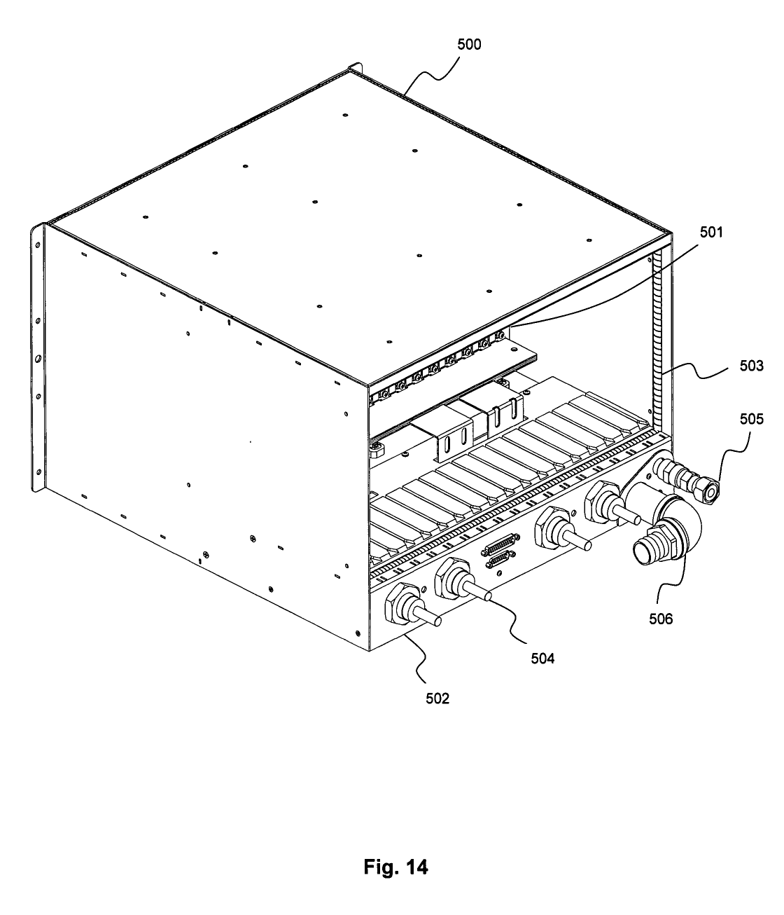

FIG. 14 shows the chassis for an exemplary system: The chassis 500 consists primarily of a sheet metal enclosure that provides structural strength and precision features to align the backplane 501, chassis manifold assembly 502, and the individual blades 110. It also has EMI panels and slot blanks with gaskets 503 to provide a Faraday cage to attenuate potential electromagnetic (EM) emissions. In addition, the chassis has provisions for housing DC filters 504 to reduce EM conducted emissions in and out of the chassis along the power lines. Redundant −48VDC power lines into the chassis that are each sized for over 9000 W, are included in the exemplary system as well. Additional chassis embodiments include means for forced air convection through sections of the chassis. Deployment of air-cooled or spray cooled RTMs that enable the use of higher-powered network (GigE, Infiniband) chips, graphics chips, or other components that cannot be air-cooled. This provides additional flexibility and great use of the shallow depth of the chassis 500. Also in the exemplary system, individual blades can be single-handedly “fluidly and electrically hot-swapped” in and out of the chassis quickly and without the need for tools. This “fluid and electrical hot-swapping” can occur while the system and other blades continue running similar to how electrical hot swapping is achieved. The closed loop coolant system will not be breached since blind-mate shut-off fluid couplings 505 and 506 are employed. Service of individual boards can be performed and servicing of the coolant system will not be required. More specifically, the coolant in the system will not be exposed to airborne contaminants in a harsh environment nor will de-gassing procedures be necessary to prevent excess pressures within the system. The inherent advantages of the Hybrid “fluid and electrical hot-swappable” design is critical for systems that require two-level maintenance, close to 100% up-time, ease of serviceability and modularity in a blade system. The chassis manifold assembly 502 is an aluminum block with separate cavities for the supply and return sides (not shown). There are shut-off blind-mate connector halves for every slot on both the supply and return side. The manifold assembly 502 is sized for acceptable pressure drop with up to 8LPM flow through the supply side and a 2-phase mixture on the return side. This manifold assembly 502 can also be designed as a Low Momentum Loss Chassis Manifold as disclosed in U.S. Patent Application Number 2005/0195570 and U.S. Pat. No. 6,958,911. The backplane 501 defines the board size, alignment features for the manifold, alignment features for the blade 110, and alignment features for the chassis frame (not shown).

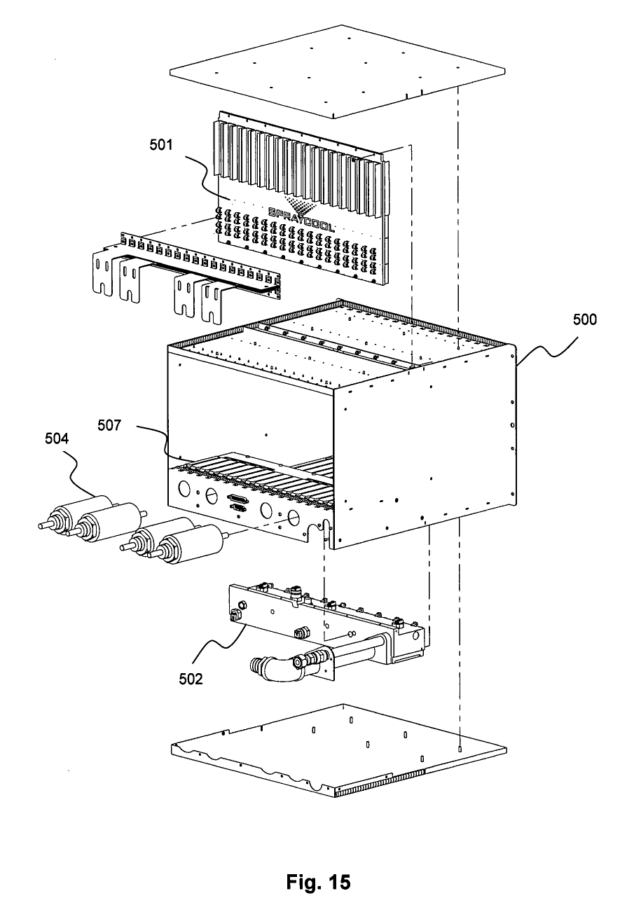

FIG. 15 shows an exploded view of the chassis 500 as discussed in FIG. 14. It includes the backplane 501, chassis 500, card guide 506, manifold assembly 502 and the DC filters 504.

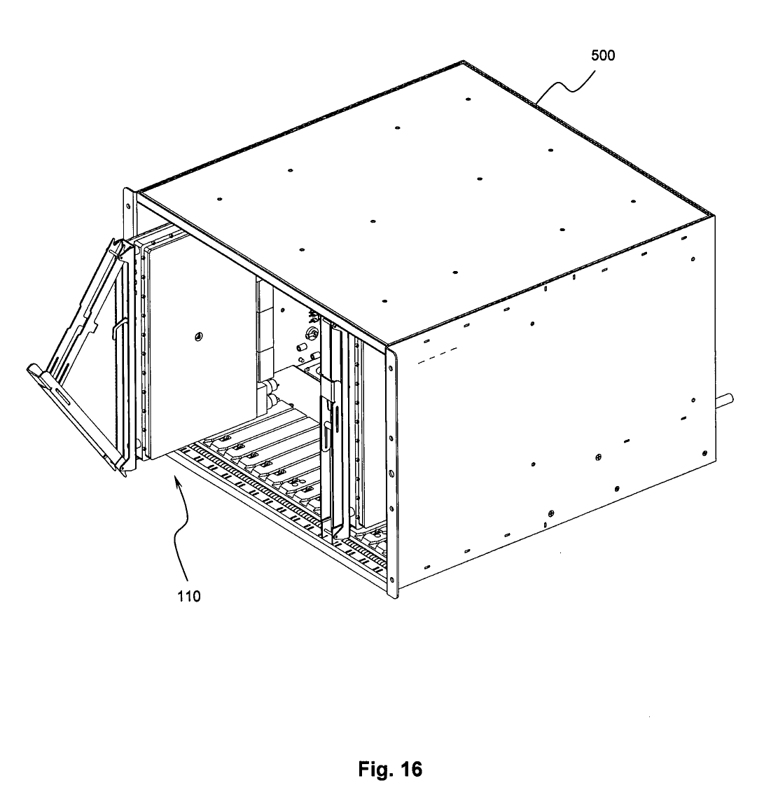

FIG. 16 shows the chassis 500 with a blade 110 fully inserted in a slot. Another blade is in the ejected position.

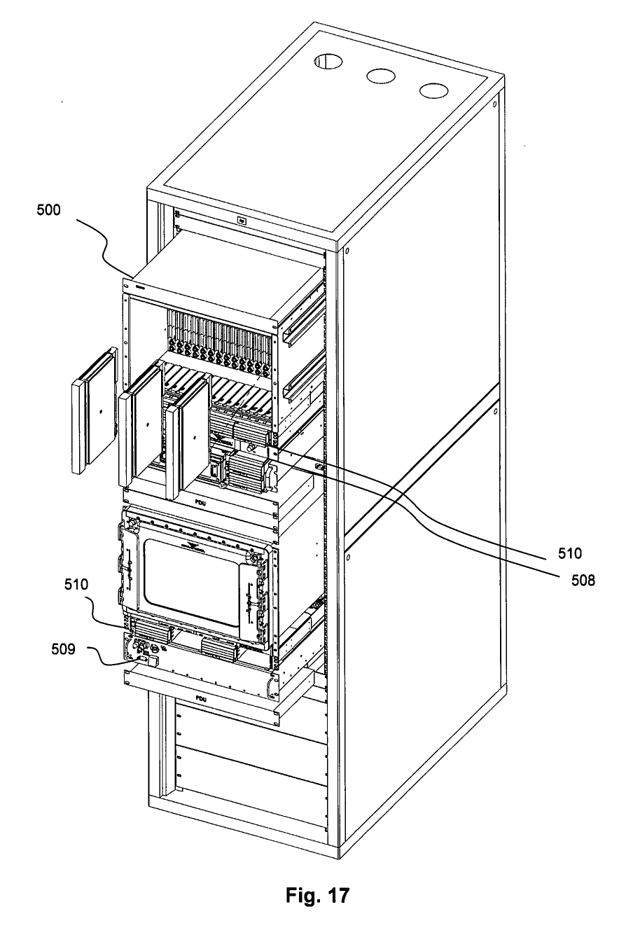

FIG. 17 shows the chassis 500 inserted in a rack with a fully supported closed loop system which includes a DC power supply 510 and a thermal management unit 508. The thermal management unit (TMU) 508 provides continuous cooling and blades and electronics can be hooked up and disconnected at will. Since a large number of blades can be operating at any given time under this system, it provides a high reliability and uptime given the “hot swappable” capability of the design.

The electrical system has the capability to monitor water leak sensors, which may be implemented to determine the status of the water lines that supply water for the secondary cooling loop to the rack, and to control water shut off valves should leaks be detected. The system also has the capability to monitor the temperature of the coolant exiting the HX 509 and controls the flow rate of the water into the liquid to liquid HX 509 using a closed loop control system. The actual water flow is adjusted with a valve. This control minimizes the use of water and maintains a more isothermal temperature within the system. Individual control for each TMU/HX is preferable since it allows for future optimized control where multiple TMUs 508 are implemented. The system has the capability to monitor coolant leaks, both the primary coolant (e.g. Fluorinert), and the secondary liquid (i.e. the water, for example, in exchange loop of the HX 509) as well. The description above is for illustrative purposes, and by no means limits the electrical/software system to the features disclosed.

An LCD panel (not shown) on the front of the TMU allows users to monitor statuses and change system variables (e.g. coolant flow rates, discharge pressure, etc.).

The TMU includes two off the shelf hot swappable power supplies 510 that feed power to the control system and system pumps. The power supplies 510 bring in, for example, 208 or 110V and convert it to 12V and lower, but may be replaced with other power supplies that support other voltage levels. The pumps preferably run off 12V in order to be able to utilize the same server power supply architectures and form factors that are currently available in the overall solution space. The preferred pump (not shown) for this system is a magnetically coupled centrifugal pump and the power supply is preferably an off-the-shelf Valere power supply capable of over 9000 W in a 1U-19″ rack mountable package with IPMI capabilities to communicate with the Product Control System (PCS) board for appropriate power management as well. Additional embodiments include integrating the power supply into the chassis 500. It is also possible and desirable to spray cool the power supplies 510. One advantage would be to alleviate the need for the EMC filters that are currently housed within the chassis 500, in addition to enhanced thermal management of those devices.

It is preferable to select a pump that operates as close to the saturation point of the coolant as possible. The chassis 500, when fully populated can house 18 blades 110 and is sized to allow for flow rates upwards of 8LPM of Fluorinert. Any type of pump suitable of pumping Fluorinert at necessary pressures (approx 30 psi) and flow rates can be used. An optional coolant filter is preferably plumbed directly into the supply line (100% flow through) and is located between the pump manifold and the supply manifold. The filter preferably removes media down to 10 microns. Any filter media or size could be used as long as it meets system pressure drop and filtering requirements. Each blade 110 also has an individual in line particle filter that is located inboard of the supply side fluid coupling (redundant filtering is preferred). In this manner, filters can be removed and replaced easily when servicing is required. These filters remove media down to 10 microns, as well. Similarly, any filter media or size could be used in the blades as long as it meets system pressure drop and filtering requirements. Additionally, it is preferable to implement a chemical filter between the supply and return manifolds and it is preferably configured so that only a portion of the total system flow passes through it. The chemical filter removes oils, water, and coolant decomposition byproducts, and etc. should such a failure occur. The bypass flow arrangement also has advantages primarily that the pump never dead heads completely thereby allowing the system to be run without any blades in place. The pump manifold also preferably contains check valves for each of the pump connections. In this configuration any particular pump is prevented from pumping liquid coolant back through the other pumps and into the reservoir. It also allows the pump to be removed or serviced while the system is running (i.e. hot-swapped). Preferably a pump reservoir check valve may also be included that provides a precision surface for the pump to mount to the reservoir and preferably a dual o-ring configuration is implemented at this location. With this configuration after the O-rings engage, the pump pushes the valve open thereby allowing coolant flow. The pump can be removed from the system in the reverse process, and in either process minimal coolant is lost.

The supply/return tubing assemblies utilize short lengths of flexible tubing, so that permeation (both of coolant and of surrounding gasses) is minimized. At a minimum, there is a supply assembly to carry up to 8LPM from the TMU 508 (pump) to the chassis and a return assembly to carry all the return liquid-vapor mixture from the chassis to the TMU 508. A level sensor determines the amount of coolant in the system. It is preferably mounted to the HX/Reservoir. The heat exchanger (HX) 509, in the preferred embodiment, is an aluminum bar and plate cross flow heat exchanger mounted within an aluminum housing. The HX 509 is preferably mounted at the top of the reservoir and coolant flows down an incline to the pumps. The angled reservoir reduces the total coolant volume in the system which further reduces cost and weight. The HX 509 is also preferably insulated to reduce condensation potential. Other HX types may be used, in the scope of this invention. Tubing that is used to connect the TMU 508 to the chassis 500 is preferably Tygothane brand polyethylene tubing. Other embodiments may utilize a custom, multilayer tubing wherein the inside layer is designed to reduce coolant permeation and the outside layer is to reduce air permeation into the system. The middle layer provides optimal structural characteristics for bending and pull strength while maintaining its structural characteristics. Other embodiments utilize convoluted metal tubing for minimal leakage and maximum pressure/strength capabilities, but there are no limitations on the tubing used, apart from compatibility with the fluids selected and permeation considerations.

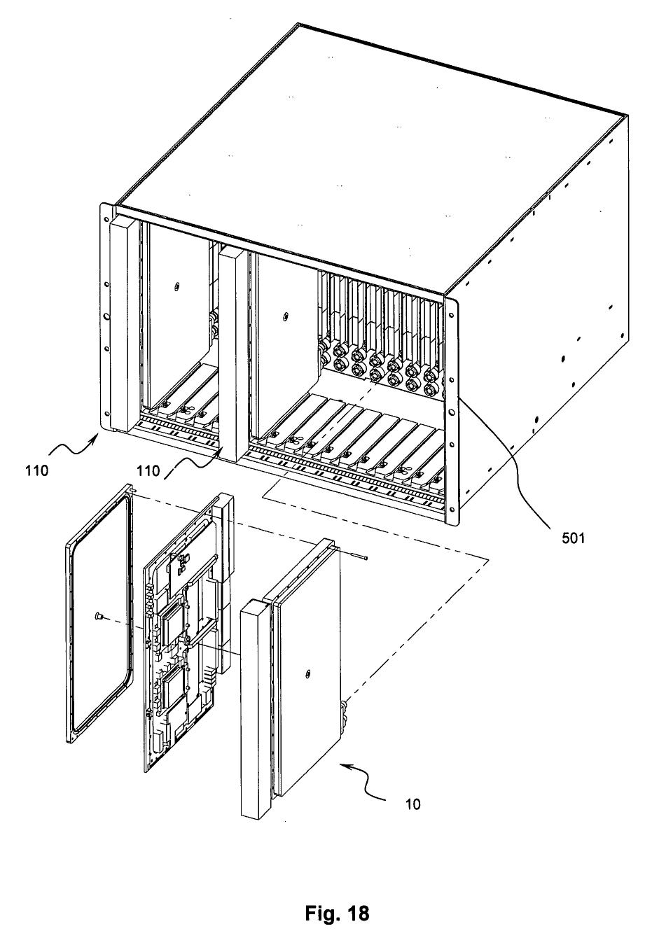

FIG. 18 shows an additional view of the chassis illustrating the backplane 501. Two blades 110 are installed and an exploded view of a third hybrid clamshell system assembly 10 is ready for installation.

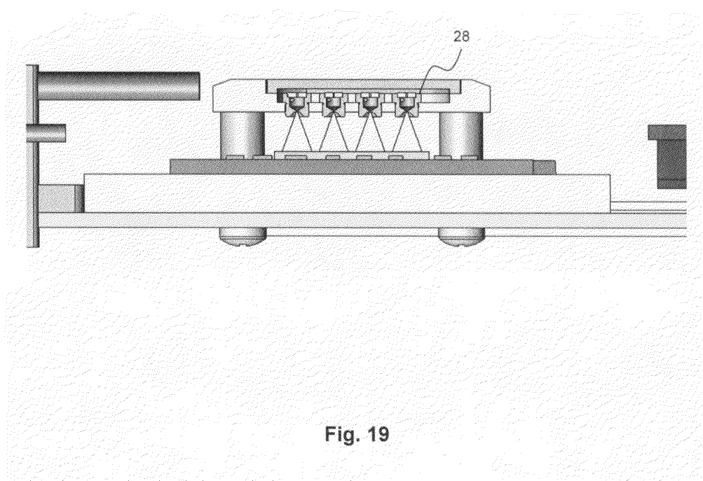

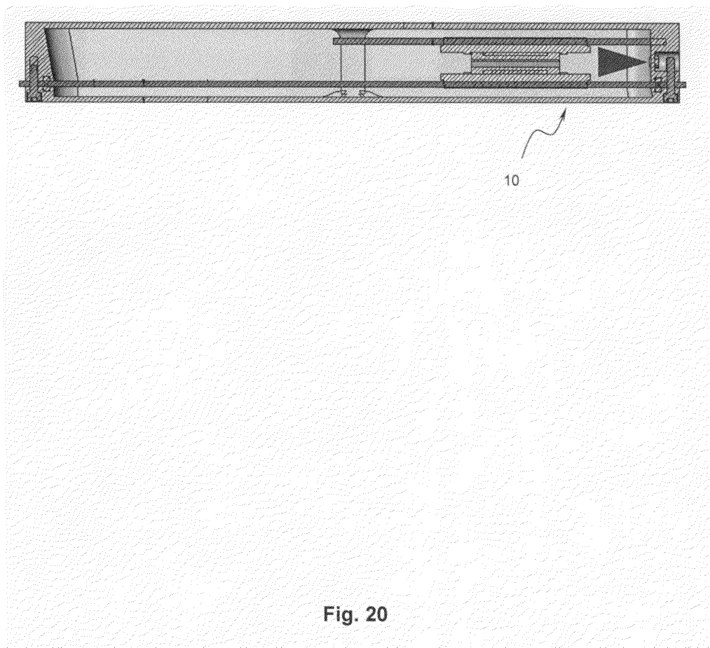

FIG. 19 shows a view of an included spray module 28 in the top down spray pattern configuration. FIG. 20 shows the narrow gap spray configuration.

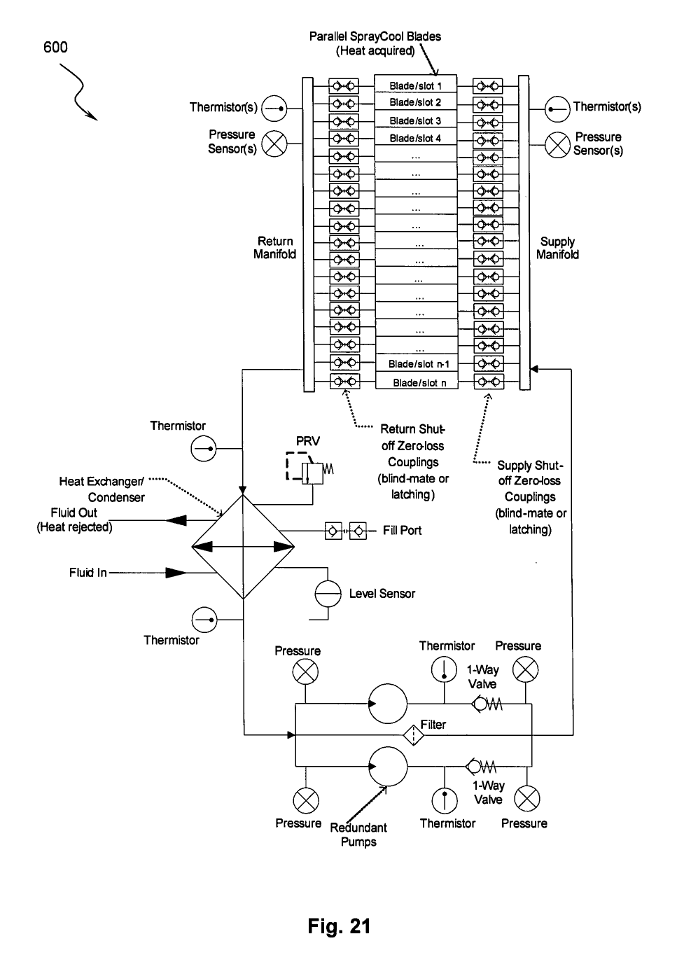

FIG. 21 is a mechanical block diagram 600 of the entire closed loop system.

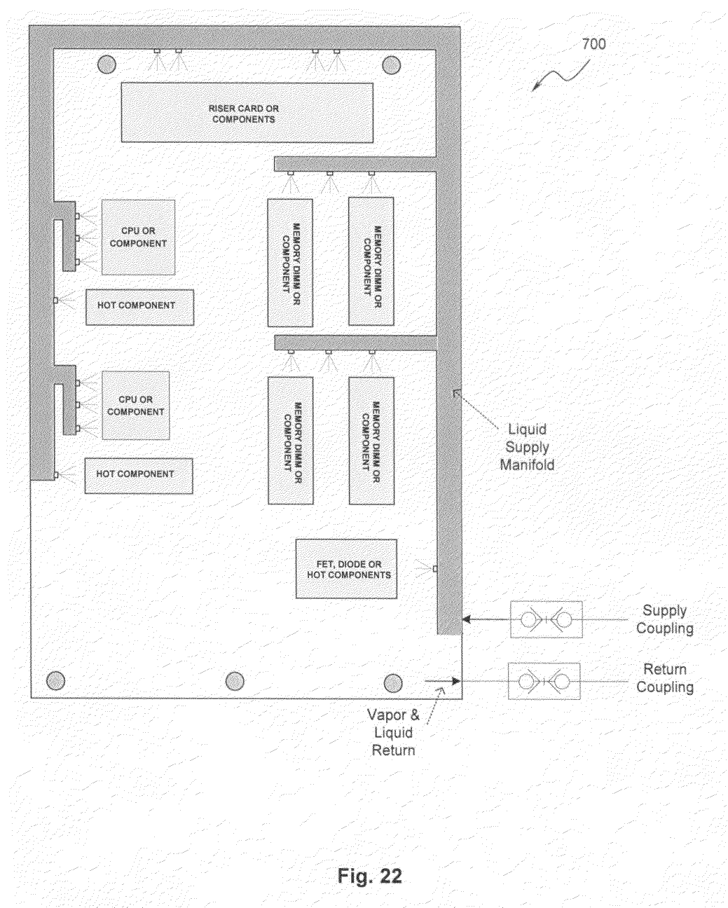

FIG. 22 is a mechanical block diagram 700 which shows the various spray module configurations and their relation to the critical thermal components.

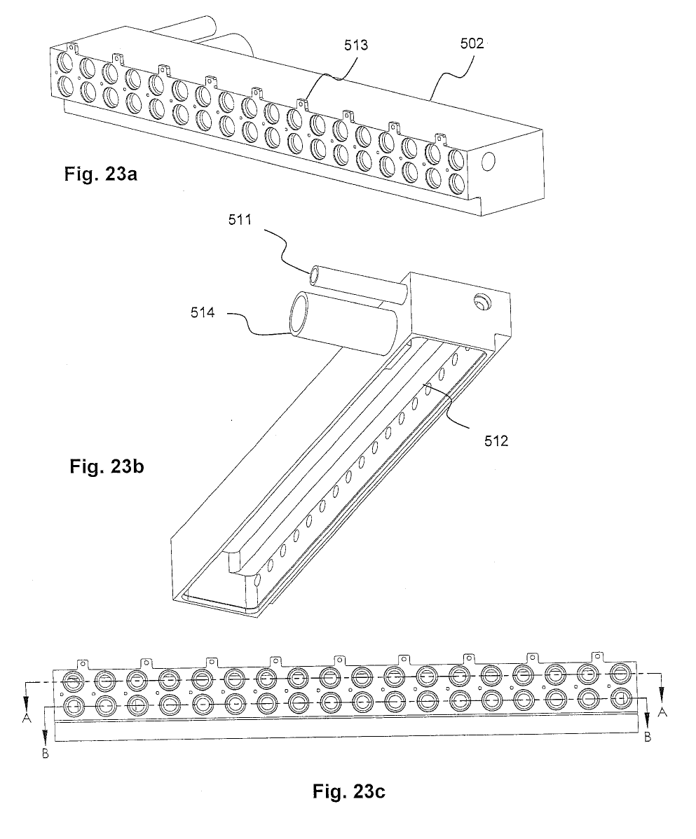

FIGS. 23a-23c show the manifold assembly 502. With this configuration, the coolant from the pump enters the supply line 511 and continues into the manifold 512. In addition, coolant exiting the individual hybrid clamshell systems also enters the manifold through the backplane connections 513. The coolant then exits through the return line 514 in the manifold assembly 502 and continues to the heat exchanger. The manifold assembly 502 can be designed such that the coolant supply can be pre-heated to various levels with the return flow.

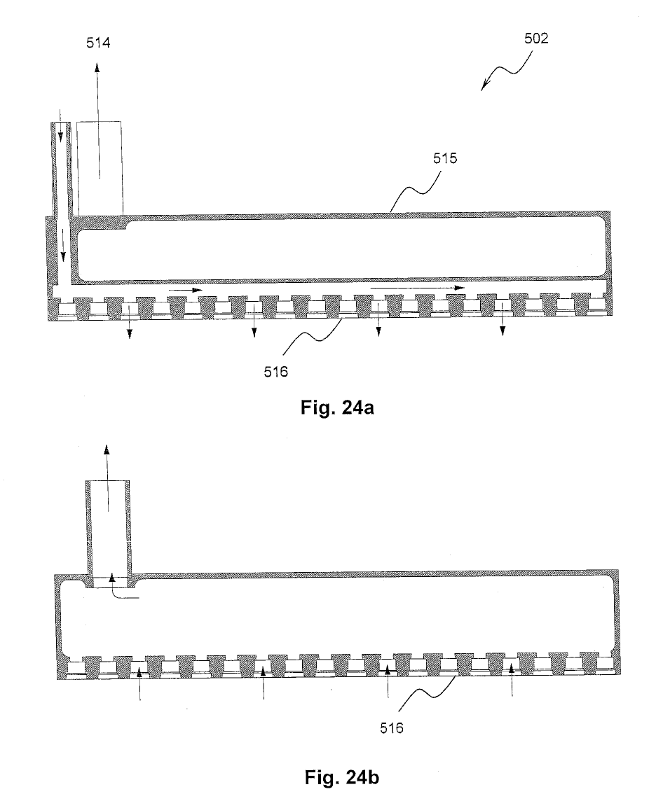

FIGS. 24a and 24b show a top down view of the manifold assembly 502. As can be seen the coolant enters from both the pump and the blade coolant connections 516 and into the return reservoir 515 before exiting through the return line to the heat exchanger.

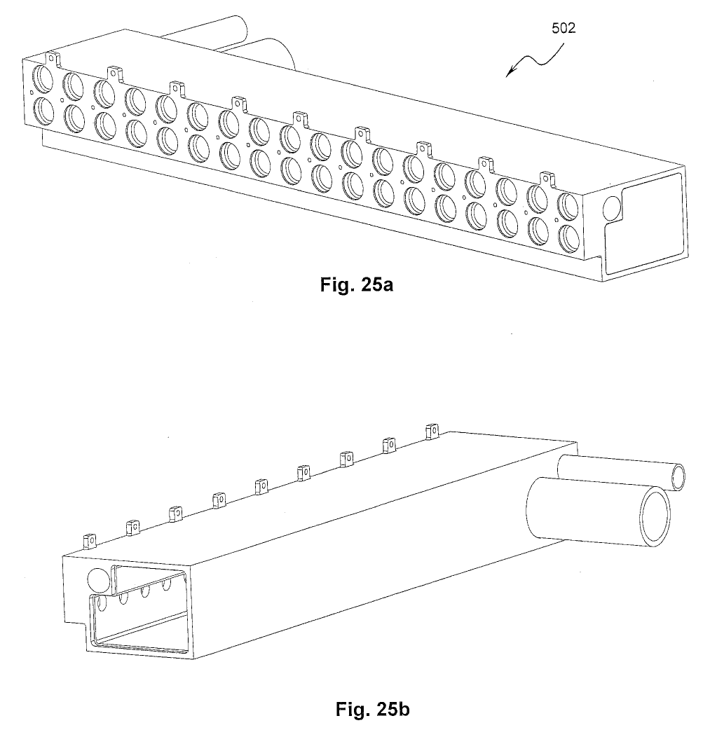

FIGS. 25a and 25b illustrate another extruded embodiment of the manifold assembly 502 which operates in the same manner as described above.

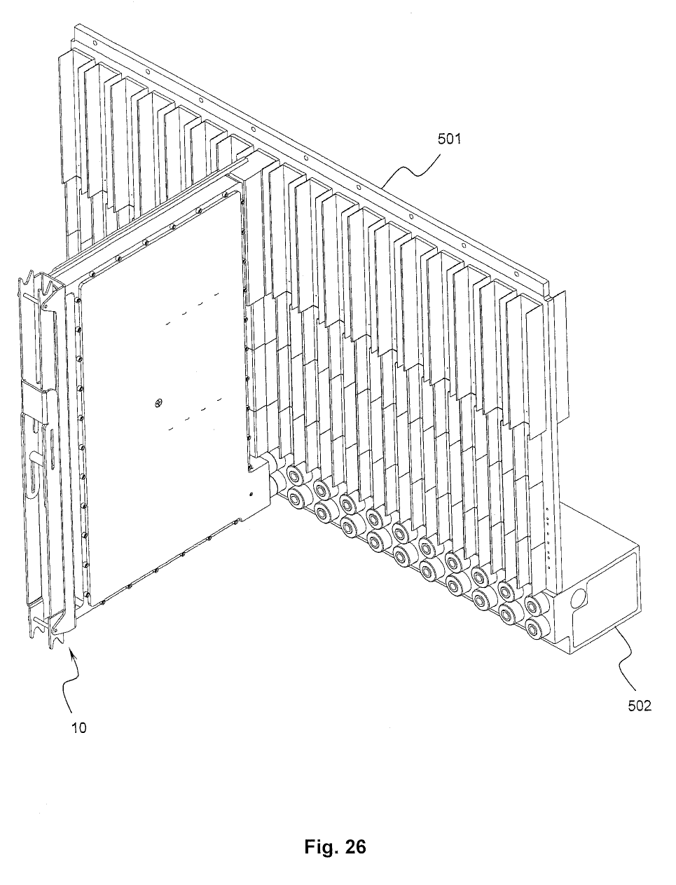

FIG. 26 shows the manifold assembly 502 attached to the backplane 501 with a hybrid clamshell system assembly 10 installed in a closed and fully locked position.

In an additional embodiment, the chassis can also incorporate an active air purge system. An active air purge system provides the ability for the liquid cooling system to heal itself in the event of air ingress and regulate internal pressures for optimal cooling. An active air purge system was previously filed in U.S. Provisional Patent Application No. 60/775,496 on Feb. 21, 2006.

In a further embodiment, the system can reject its waste heat to a TMU that is connected to cooling tower water (i.e., bypasses any chillers that may be used in land-based data centers, ship-based data centers, telecom facilities, etc.). This approach to heat rejection significantly raises the system energy efficiency, and lowers the cost of ownership of the technology.

In yet another embodiment, the clamshell enclosure could enclose any fraction of a board instead of a large majority of the multi-processor board. The remaining un-enclosed section of the board could be cooled by other means, hence, the term hybrid cooling. Another embodiment would enable some components to be cooled with liquid cooling (where all components are wetted by the coolant, and some with a spray nozzle (preferably with a cold plate interface), all on the same board.

Similar to the paragraph above, the chassis could use other methods to acquire a fraction of the heat produced in the chassis. The current chassis acquires almost all the heat into the Fluorinert (a 3M manufactured fluid used in the system), except for a few minor components on the multi-processor board and the lower power components on the rear transition module (RTM). An example of multiple thermal solutions in a future embodiment could include a chassis that had half of the slots air-cooled and half cooled by clamshell blades.

One of the goals of this system is to provide a solution which enables dense and narrow pitch applications or narrow-gap side-spray (NGSS). It is important to note that the NGSS technology has enabled the hybrid system solution. The development has included several iterations of analysis, prototyping, data collection, and correlation to achieve the objective. The most optimized solutions to date show 13° C. and 18° C. temperature differences between the diode and coolant spray inlet on 100 Watt thermal test kits (worst case CPUs) for the 130 nm (2.2 GHz—ceramic package) and 90 nm (2.6 GHz—organic package) processing of Opterons, respectively. This solution has resulted in reducing the quantity of atomizers from twelve to three, reducing flow-rates per CPU from 140 mL/min to 60 mL/min, decreasing thermal resistance, and reducing susceptibility to fluctuations in coolant pressure. This will allow high power and high heat flux processors (AMD Opteron—100 Watt) to perform in narrow pitches in harsh thermal environments. The NGSS technology can also be used with multi-core die, and can be deployed in both non-harsh and harsh environments.

In yet another embodiment, the clamshell enclosure and modular multi-processor board (MMPB) currently allow for user definable signals to be brought from the wet to the dry side of the enclosure. There are solder pads on the inside of the board which are electrically connected, with vias through the PCB, to a connector on the front panel. These are used for data acquisition, system start-up, and as test/diagnostic points. The MMPB is a dual AMD Opteron processor board. It can run two dual-core Opterons and is able to run multi-core CPUs, i.e., 4 cores and beyond. It can accept up to 16 GB of memory. It has the following I/O capabilities: IB, Gigabit Ethernet, PCIe, SATA, USB, RS232, HT (AMD Hypertransport), and other general purpose I/O. It has a daughter card that functions as a baseboard management controller (BMC) that functions as slave device to the shelf manager via Intelligent Platform Management Interface (IPMI) protocol. It has another daughter card that converts PCIe to IB, which is easily upgradeable to convert to other high-speed signals all of which are configurable for liquid cooling within the scope of the instant invention. Liquid cooling includes spray, microchannel, immersion, cold plate, etc. The clamshell design enables use of off-the-shelf backplane connectors to reduce cost, increase density, and increase high-speed signal integrity.

The foregoing description of the embodiments of the invention has been presented for the purpose of illustration; it is not intended to be exhaustive or to limit the invention to the precise forms disclosed. For example, many of the fastening, connection, manufacturing, and other means and components that are described in various embodiments are widely known in the relevant field, and their exact nature or type is not necessary for a person of ordinary skill in the art or science to understand the invention. Persons skilled in the relevant art can appreciate that many modifications and variations are possible in light of the above teachings. It is therefore intended that the scope of the invention be limited not by this detailed description, but rather by the claims appended hereto.

We claim:

1. A hybrid clamshell blade system comprised of:
A multipart enclosure;
An electronic circuit board mounted to a first part of said multipart enclosure, said circuit board bearing at least one electronic device;
A plurality of atomizers contained within at least one part of said multipart enclosure for depositing a cooling liquid on said at least one electronic device;
A plurality of fluid shut-off couplings to allow said cooling liquid to enter and exit said multipart enclosure;
A manifold disposed within a side wall of at least one part of said multipart enclosure for transporting said cooling liquid from said entering shut-off coupling to said atomizers and back to said exiting shut-off coupling; and
A thin film of coolant formed on said at least one electronic device for transferring heat therefrom.

2. The hybrid clamshell blade system of claim 1, wherein said electronic circuit board is a blade server.

3. The hybrid clamshell blade system of claim 1, wherein said electronic circuit board is any type of printed circuit board.

4. The hybrid clamshell blade system of claim 1, wherein at least one part of said multipart enclosure seals to said electronic circuit board using o-rings.

5. The hybrid clamshell blade system of claim 1, wherein a large planar side of said multipart enclosure is supported internally by a post support member.

6. The hybrid clamshell blade system of claim 1, further comprising an inject/eject lever to provide for ease in inserting and ejecting said hybrid clamshell blade system.

7. The hybrid clamshell blade system of claim 1, wherein said plurality of atomizers are disposed to dispense said cooling liquid in a direction parallel to said circuit board through a narrow gap.

8. The hybrid clamshell blade system of claim 1, wherein said electronic circuit board uses an inert coolant compatible thermal interface material in certain thermal hot spots.

9. The hybrid clamshell blade system of claim 1, further comprising a plurality of spray module extensions for disposing said plurality of atomizers.

10. A hybrid clamshell blade system comprised of:
A multipart enclosure;
An electronic circuit board bearing at least one electronic component partially sealed within said multipart enclosure;
A plurality of atomizers contained within said multipart enclosure for depositing a cooling liquid on said electronic component;
A plurality of fluid shut-off couplings to allow said cooling liquid to enter and exit said multipart enclosure;
A manifold disposed within a side wall of said multipart enclosure for transporting said cooling liquid from said entering shut-off coupling to said atomizers and back to said exiting shut-off coupling; and
An inject/eject lever for inserting and removing said hybrid clamshell blade system.

11. The hybrid clamshell blade system of claim 9, wherein said multipart enclosure seals to said electronic circuit board using o-rings.

12. The hybrid clamshell blade system of claim 9, wherein said multipart enclosure is supported internally by a post support member.

13. The hybrid clamshell blade system of claim 9, further comprising air cooling to a portion of said electronic circuit board that is not enclosed by said multipart enclosure.

14. A hybrid clamshell cooling system comprised of:
A rack;
A plurality of hybrid clamshell blade systems disposed within said rack;
A thermal control unit, said thermal control unit further comprised of a pump, a heat exchanger and a control unit, and
A manifold fluidly connected to said thermal control unit and said plurality of hybrid clamshell blade systems to distribute coolant to each of said plurality of hybrid clamshell blade systems.

15. The hybrid clamshell cooling system of claim 13, further comprising an active vent system.

16. The hybrid clamshell cooling system of claim 13, further comprising a pump manifold incorporating one or more check valves to allow an exchange of pumps during operation.

17. The hybrid clamshell cooling system of claim 13, further comprising a one or more particulate filters.

18. A hybrid clamshell cooling system comprised of:
A rack;
A plurality of hybrid clamshell blade systems disposed within said rack and connected to a backplane, said backplane connects to said plurality of hybrid clamshell blade system both fluidly and electrically;
A thermal control unit, said thermal control unit further comprised of a pump, a heat exchanger and a control unit, and
A manifold fluidly connected to said thermal control unit and said plurality of hybrid clamshell blade systems to distribute coolant to each of said plurality of hybrid clamshell blade systems.

19. The hybrid clamshell cooling system of claim 18, further comprising an active vent system.

20. The hybrid clamshell cooling system of claim 18, further comprising a pump manifold incorporating one or more check valves to allow an exchange of pumps during operation.

21. The hybrid clamshell cooling system of claim 18, further comprising a one or more particulate filters.

22. A hybrid clamshell blade system comprised of:
A multipart enclosure supported internally by a post support member;
An electronic circuit board bearing at least one electronic component partially sealed within said multipart enclosure, said multipart enclosure sealing to said electronic component using o-rings;
A plurality of atomizers contained within said multipart enclosure for depositing a cooling liquid on said electronic component;
A plurality of fluid shut-off couplings to allow said cooling liquid to enter and exit said multipart enclosure;
A manifold disposed within a side wall of said multipart enclosure for transporting said cooling liquid from said entering shut-off coupling to said atomizers and back to said exiting shut-off coupling; and
An inject/eject lever for inserting and removing said hybrid clamshell blade system.
